(19) United States
(12) Patent Application Publication
(10) Pub. No.: US 2019/0362669 A1
(43) Pub. Date: Nov. 28, 2019

(54) PIXEL DRIVING CIRCUIT, DRIVING METHOD THEREOF, AND DISPLAY PANEL

(71) Applicant: Wuhan China Star Optoelectronics Semiconductor Display Technology Co., Ltd., Wuhan (CN)

(72) Inventor: Jianhong LIN, Wuhan, Hubei (CN)

(21) Appl. No.: 16/255,442

(22) Filed: Jan. 23, 2019

Related U.S. Application Data
(63) Continuation of application No. PCT/CN2018/096050, filed on Jul. 18, 2018.

(30) Foreign Application Priority Data
May 23, 2018 (CN) 201810502180.1

(51) Int. Cl. G09G 3/3225; G06F 3/041; H01L 27/32; H01L 51/00; G06F 3/044

(52) U.S. Cl. CPC G09G 3/3225; G06F 3/0412; G06F 3/044; H01L 27/3244; H01L 51/0097; H01L 27/323

(57) ABSTRACT

The present invention teaches a pixel driving circuit including a base pixel circuit, a touch control circuit, and a switch. The base pixel circuit has a first terminal connected to a DC high voltage signal, and a second terminal connected to a positive terminal of an electronic lighting element. The electronic lighting element has a negative terminal connected to a DC low voltage signal. The base pixel circuit drives or turns off the illumination of the electronic lighting element. The touch control circuit is connected to a junction between the negative terminal of the electronic lighting element and the DC low voltage signal through the switch. Based on whether the base pixel circuit drives the electronic lighting element to illuminate, the touch control circuit turns on or off the switch accordingly. The present invention therefore resolves the existing touch display panel's thickness and inflexible issues.

### CROSS-REFERENCE TO RELATED APPLICATIONS

This application is a continuing application of PCT Patent Application No. PCT/CN2018/096050, filed on Jul. 18, 2018, which claims priority to Chinese Patent Application No. 201810502180.1, filed on May 23, 2018, both of which are hereby incorporated herein by reference in their entireties.

### FIELD OF THE INVENTION

The present invention is generally related to the field of display technology, and more particularly to a pixel driving circuit, its driving method, and a display panel.

### BACKGROUND OF THE INVENTION

Compared to conventional liquid crystal display (LCD) panel, Active Matrix Organic Light Emitting Diode (AMOLED) panel has faster response, higher contrast, and wider viewing angle. AMOLED therefore is gaining more attention.

AMOLED is driven to illuminate by pixel driving circuit. As shown in FIG. 1, the pixel driving circuit has a 3T1C design, which includes a switch transistor STFT, a driving transistor DTFT, a control transistor ETFT, and a storage capacitor Cst. The switch transistor STFT controls the input of data signal. The driving transistor DTFT controls the flow of driving current into OLED according to the data signal. The storage capacitor Cst provides maintaining voltage to the DTFT. The control transistor ETFT controls whether the driving current flows through the OLED and therefore whether the OLED illuminates.

In recent years, touch control function is widely popular on various display panels, especially for mobile devices. A touch panel has become a de facto component to smart phones. However, most display panels adopts external touch panels. The manufacturing process is complicated, new material is required for making flexible panels, and therefore cost and thickness are both higher.

### SUMMARY OF THE INVENTION

The technical issues addressed by the present invention is to provide a pixel driving circuit, a related driving method, and a display pane, where the touch control function is integrated with the pixel driving circuit. The present invention as such resolves the existing touch display panel's thickness and inflexible issues. The manufacturing complexity is reduced and the cost for purchasing external touch panel is saved.

To resolve the above technical issues, the present invention provides a pixel driving circuit comprising a base pixel circuit, a touch control circuit, and a switch, wherein

the base pixel circuit has a first terminal connected to a DC high voltage signal, and a second terminal connected to a positive terminal of an electronic lighting element; the electronic lighting element has a negative terminal connected to a DC low voltage signal; the base pixel circuit drives or turns off the illumination of the electronic lighting element;

the touch control circuit is connected to a junction between the negative terminal of the electronic lighting element and the DC low voltage signal through the switch; and, based on whether the base pixel circuit drives the electronic lighting element to illuminate, the touch control circuit turns on or off the switch accordingly.

If the base pixel circuit drives the electronic lighting element to illuminate, the switch is opened and the touch control circuit is prevented from functioning as the touch control circuit is disconnected from the DC low voltage signal; and

if the base pixel circuit prevents the electronic lighting element from illuminating, the switch is closed and the touch control circuit functions as the touch control circuit is connected to the DC low voltage signal.

The touch control circuit comprises an inductive capacitor, a coupling capacitor, an operational capacitor, and an operational amplifier, wherein

the inductive capacitor has a terminal connected to a touch sensitive line, and another terminal connected to a terminal of the switch, a terminal of the coupling capacitor, a terminal of the operational capacitor, and a first input terminal of the operational amplifier;

another terminal of the coupling capacitor is connected to ground;

the operational capacitor has another terminal connected to an output terminal of the operational amplifier, thereby forming a negative feedback amplification circuit with the operational amplifier; and

a second input terminal of the operational amplifier is connected to an internal working voltage signal.

The base pixel circuit comprises a switch transistor a driving transistor, a control transistor, and a storage capacitor, wherein

the switch transistor has the gate connected to a scan signal, the drain connected to a data signal, and the source connected to a terminal of the storage capacitor and the gate of the driving transistor;

the driving transistor has the drain connected to the DC high voltage signal, and the source connected to the drain of the control transistor;

the control transistor has the gate connected to a control signal, and the source connected to the positive terminal of the electronic lighting element; and

another terminal of the storage capacitor is connected to the DC high voltage signal.

The electronic lighting element is an organic light emitting diode (OLED).

The present invention also teaches a driving method for a pixel driving circuit. The pixel driving circuit comprises comprising a base pixel circuit, a touch control circuit, and a switch, where the base pixel circuit has a first terminal connected to a DC high voltage signal and a second terminal connected to a positive terminal of an electronic lighting element, the electronic lighting element has a negative terminal connected to a DC low voltage signal, the touch control circuit is connected to a junction between the negative terminal of the electronic lighting element and the DC low voltage signal through the switch. The driving method comprises the steps of

determining a current operation state of the base pixel circuit, where the current operation state of the base pixel circuit is either driving the electronic lighting element to illuminate or preventing the electronic lighting element from illuminating; and

controlling whether the touch control circuit to function or not by closing or opening the switch in accordance with the current operation state of the base pixel circuit.

The step of controlling whether the touch control circuit to function or not comprises the step of

if the base pixel circuit drives the electronic lighting element to illuminate, the switch is opened and the touch control circuit is prevented from functioning as the touch control circuit is disconnected from the DC low voltage signal.

The step of controlling whether the touch control circuit to function or not comprises the step of

if the base pixel circuit prevents the electronic lighting element from illuminating, the switch is closed and the touch control circuit functions as the touch control circuit is connected to the DC low voltage signal.

The touch control circuit comprises an inductive capacitor, a coupling capacitor, an operational capacitor, and an operational amplifier, wherein

the inductive capacitor has a terminal connected to a touch sensitive line, and another terminal connected to a terminal of the switch, a terminal of the coupling capacitor, a terminal of the operational capacitor, and a first input terminal of the operational amplifier;

another terminal of the coupling capacitor is connected to ground;

the operational capacitor has another terminal connected to an output terminal of the operational amplifier, thereby forming a negative feedback amplification circuit with the operational amplifier; and

a second input terminal of the operational amplifier is connected to an internal working voltage signal.

The base pixel circuit comprises a switch transistor, a driving transistor, a control transistor, and a storage capacitor, wherein

the switch transistor has the gate connected to a scan signal, the drain connected to a data signal, and the source connected to a terminal of the storage capacitor and the gate of the driving transistor;

the driving transistor has the drain connected to the DC high voltage signal, and the source connected to the drain of the control transistor;

the control transistor has the gate connected to a control signal, and the source connected to the positive terminal of the electronic lighting element; and

another terminal of the storage capacitor is connected to the DC high voltage signal.

The electronic lighting element is an organic light emitting diode (OLED).

The present invention also teaches a display panel, which comprises a pixel driving circuit, wherein the pixel driving circuit comprises a base pixel circuit, a touch control circuit, and a switch, wherein

the base pixel circuit has a first terminal connected to a DC high voltage signal, and a second terminal connected to a positive terminal of an electronic lighting element; the electronic lighting element has a negative terminal connected to a DC low voltage signal; the base pixel circuit drives or turns off the illumination of the electronic lighting element;

the touch control circuit is connected to a junction between the negative terminal of the electronic lighting element and the DC low voltage signal through the switch; and, based on whether the base pixel circuit drives the electronic lighting element to illuminate, the touch control circuit turns on or off the switch accordingly.

If the base pixel circuit drives the electronic lighting element to illuminate, the switch is opened and the touch control circuit is prevented from functioning as the touch control circuit is disconnected from the DC low voltage signal; and

if the base pixel circuit prevents the electronic lighting element from illuminating, the switch is closed and the touch control circuit functions as the touch control circuit is connected to the DC low voltage signal.

The touch control circuit comprises an inductive capacitor, a coupling capacitor, an operational capacitor, and an operational amplifier, wherein

the inductive capacitor has a terminal connected to a touch sensitive line, and another terminal connected to a terminal of the switch, a terminal of the coupling capacitor, a terminal of the operational capacitor, and a first input terminal of the operational amplifier;

another terminal of the coupling capacitor is connected to ground;

the operational capacitor has another terminal connected to an output terminal of the operational amplifier, thereby forming a negative feedback amplification circuit with the operational amplifier; and

a second input terminal of the operational amplifier is connected to an internal working voltage signal.

The base pixel circuit comprises a switch transistor, a driving transistor, a control transistor, and a storage capacitor, wherein

the switch transistor has the gate connected to a scan signal, the drain connected to a data signal, and the source connected to a terminal of the storage capacitor and the gate of the driving transistor;

the driving transistor has the drain connected to the DC high voltage signal, and the source connected to the drain of the control transistor;

the control transistor has the gate connected to a control signal, and the source connected to the positive terminal of the electronic lighting element; and

another terminal of the storage capacitor is connected to the DC high voltage signal.

The electronic lighting element is an organic light emitting diode (OLEO).

The advantages of the present invention are as follows. The pixel driving circuit of the present invention includes a base pixel circuit driving or turning off the illumination of the electronic lighting element, and a touch control circuit which turns on or off the touch sensitive function based on whether the base pixel circuit drives or turns off the electronic lighting element. The present invention therefore integrates touch control function with the pixel driving circuit. The present invention as such resolves the existing touch display panel's thickness and inflexible issues. The manufacturing complexity is reduced and the cost for purchasing external touch panel is saved.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 schematic circuit diagram showing a conventional pixel driving circuit.

FIG. 2 is a functional block diagram showing a pixel driving circuit according to an embodiment of the present invention.

FIG. 3 is a schematic circuit diagram showing a pixel driving circuit according to an embodiment of the present invention.

FIG. 4 is a schematic diagram showing the operation of the pixel driving circuit of FIG. 3.

FIG. 5 is another schematic diagram showing the operation of the pixel driving circuit of FIG. 3.

FIG. 6 is a flow diagram showing a driving method to the pixel driving circuit of FIG. 3.

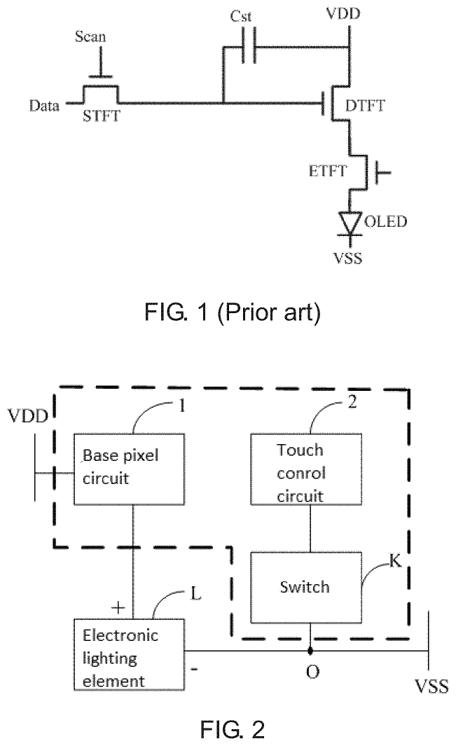

### DETAILED DESCRIPTION OF PREFERRED EMBODIMENTS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

As shown in FIG. 2, a pixel driving circuit according to an embodiment of the present invention includes a base pixel circuit 1, a touch control circuit 2, and a switch K.

The base pixel circuit 1 has a first terminal connected to a DC high voltage signal VDD, and a second terminal connected to a positive terminal (+) of an electronic lighting element L. The electronic lighting element L has a negative terminal (−) connected to a DC low voltage signal VSS. The base pixel circuit 1 drives or turns off the illumination of the electronic lighting element L.

The touch control circuit 2 is connected to a junction O between the negative terminal (−) of the electronic lighting element L and the DC low voltage signal VSS through the switch K. Based on whether the base pixel circuit 1 drives the electronic lighting element L to illuminate, the touch control circuit 2 turns on or off the switch K accordingly.

It should be noted that, through the on and off of switch K, interference (including current and signal interferences) to the touch control circuit 2 by the base pixel circuit 1 is prevented. When the base pixel circuit 1 drives the electronic lighting element L to illuminate, the switch K is opened and the touch control circuit 2 is prevented from operation as it is disconnected from the DC low voltage signal VSS. When the base pixel circuit 1 turns of the illumination of the electronic lighting element L, the switch K is closed and the touch control circuit 2 operates normally to detect touch and to output touch signal as it is connected to the DC low voltage signal VSS.

It should be understandable that the electronic lighting element L may be an OLED or other lighting element.

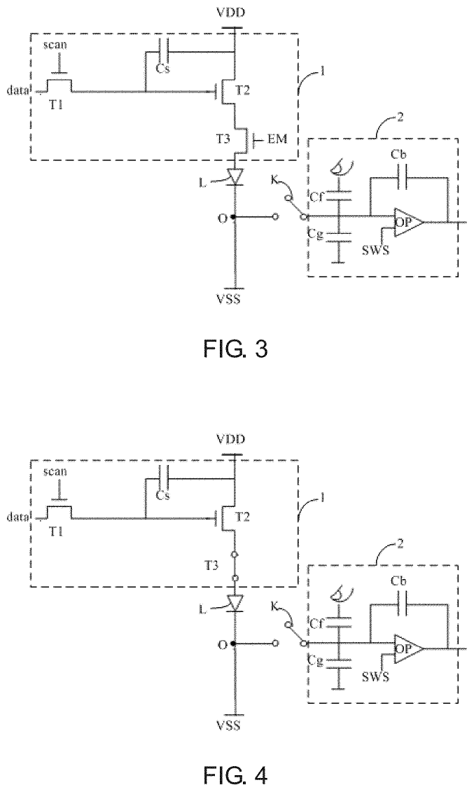

As shown in FIG. 3, the touch control circuit 2 includes an inductive capacitor Cf, a coupling capacitor Cg, an operational capacitor Cb, and an operational amplifier OP.

The inductive capacitor Cf has a terminal connected to a touch sensitive line, and another terminal connected to a terminal of the switch K, a terminal of the coupling capacitor Cg, a terminal of the operational capacitor Cb, and a first input terminal of the operational amplifier OP. Another terminal of the coupling capacitor Cg is connected to ground.

The operational capacitor Cb has another terminal connected to an output terminal of the operational amplifier OP, thereby forming a negative feedback amplification circuit with the operational amplifier OP.

A second input terminal of the operational amplifier is connected to an internal working voltage signal SWS.

The base pixel circuit 1 includes a switch transistor T1, a driving transistor T2, a control transistor T3, and a storage capacitor Cs.

The switch transistor T1 has the gate connected to a scan signal (scan), the drain connected to a data signal (data), and the source connected to a terminal of the storage capacitor Cs and the gate of the driving transistor T2.

The driving transistor T2 has the drain connected to the DC high voltage signal VDD, and the source connected to the drain of the control transistor T3.

The control transistor T3 has the gate connected to a control signal (EM), and the source connected to the positive terminal (+) of the electronic lighting element L.

Another terminal of the storage capacitor Cs is connected to the DC high voltage signal VDD.

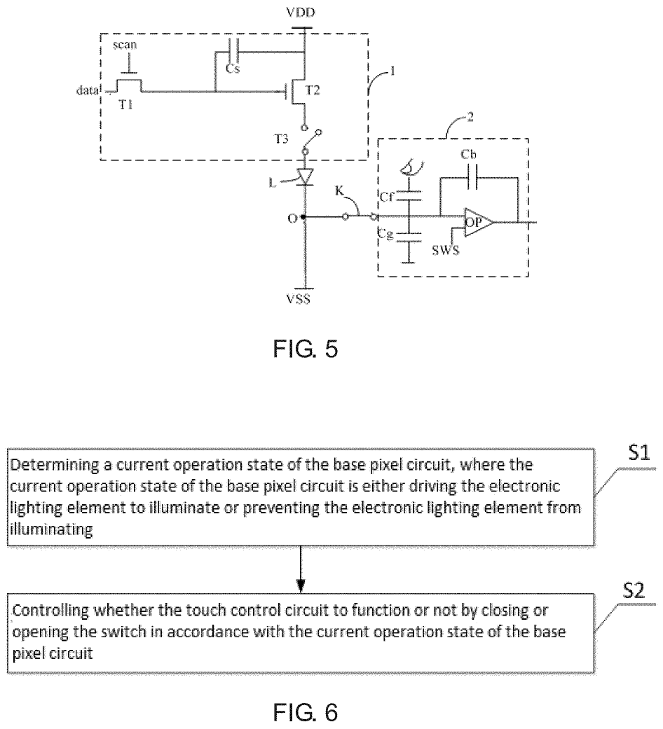

The pixel driving circuit of the present embodiment operates as follows. As shown in FIG. 4, a high-level data signal reaches the gate of the driving transistor T2 through the switch transistor T1. The driving transistor T2 is turned on so that the DC high voltage signal VDD turns on the switch transistor T3 and drives the electronic lighting element L to illuminate. At this point, the switch K is opened. The operational amplifier OP of the touch control circuit 2 cannot function as it is disconnected from the DC low voltage signal VSS. As shown in FIG. 5, a low-level data signal fails to reach the gate of the driving transistor T2 as it is blocked by the switch transistor T1. The driving transistor T2 is turned off as there is not enough voltage at its gate. The switch transistor T3 is opened and the electronic lighting element L does not illuminate as there is no current flowing through. At this point, the switch K is closed. The operational amplifier OP of the touch control circuit 2 functions normally to detect touch and to output touch signal, as it is properly connected to the DC low voltage signal VSS

As shown in FIG. 6, a driving method applied to the above pixel driving circuit according to an embodiment of the present invention includes the following steps.

Step S1: determining a current operation state of the base pixel circuit, where the current operation state of the base pixel circuit is either driving the electronic lighting element to illuminate or preventing the electronic lighting element from illuminating.

Specifically, the current operation state of the base pixel circuit is determined as follows. If the base pixel circuit provides a driving current, the current operation state is driving the electronic lighting element to illuminate. If the base pixel circuit does not provide a driving current, the current operation state is preventing the electronic lighting element from illuminating.

Step S2: controlling whether the touch control circuit to function or not by closing or opening the switch in accordance with the current operation state of the base pixel circuit.

Specifically, if the current operation state is driving the electronic lighting element to illuminate, the switch is opened so that the touch control circuit does not function. If the current operation state is preventing the electronic lighting element from illuminating, the switch is closed so that the touch control circuit functions.

Based on the pixel driving circuit described above, the present invention also teaches a display panel, which includes the above-described pixel driving circuit. The circuit has an identical structure and the details are omitted.

The advantages of the present invention are as follows. The pixel driving circuit of the present invention includes a base pixel circuit driving or turning off the illumination of the electronic lighting element, and a touch control circuit which turns on or off the touch sensitive function based on whether the base pixel circuit drives or turns off the electronic lighting element. The present invention therefore integrates touch control function with the pixel driving circuit. The present invention as such resolves the existing touch display panel's thickness and inflexible issues. The manufacturing complexity is reduced and the cost for purchasing external touch panel is saved.

Above are embodiments of the present invention, which does not limit the scope of the present invention. Any equivalent amendments within the spirit and principles of the embodiment described above should be covered by the protected scope of the invention.

What is claimed is:

1. A pixel driving circuit, comprising a base pixel circuit, a touch control circuit, and a switch, wherein
the base pixel circuit has a first terminal connected to a DC high voltage signal, and a second terminal connected to a positive terminal of an electronic lighting element; the electronic lighting element has a negative terminal connected to a DC low voltage signal; the base pixel circuit drives or turns off the illumination of the electronic lighting element;
the touch control circuit is connected to a junction between the negative terminal of the electronic lighting element and the DC low voltage signal through the switch; and, based on whether the base pixel circuit drives the electronic lighting element to illuminate, the touch control circuit turns on or off the switch accordingly.

2. The pixel driving circuit according to claim 1, wherein, if the base pixel circuit drives the electronic lighting element to illuminate, the switch is opened and the touch control circuit is prevented from functioning as the touch control circuit is disconnected from the DC low voltage signal; and
if the base pixel circuit prevents the electronic lighting element from illuminating, the switch is closed and the touch control circuit functions as the touch control circuit is connected to the DC low voltage signal.

3. The pixel driving circuit according to claim 2, wherein the touch control circuit comprises an inductive capacitor, a coupling capacitor, an operational capacitor, and an operational amplifier;
the inductive capacitor has a terminal connected to a touch sensitive line, and another terminal connected to a terminal of the switch, a terminal of the coupling capacitor, a terminal of the operational capacitor, and a first input terminal of the operational amplifier;
another terminal of the coupling capacitor is connected to ground;
the operational capacitor has another terminal connected to an output terminal of the operational amplifier, thereby forming a negative feedback amplification circuit with the operational amplifier; and
a second input terminal of the operational amplifier is connected to an internal working voltage signal.

4. The pixel driving circuit according to claim 3, wherein the base pixel circuit comprises a switch transistor, a driving transistor, a control transistor, and a storage capacitor;
the switch transistor has the gate connected to a scan signal, the drain connected to a data signal, and the source connected to a terminal of the storage capacitor and the gate of the driving transistor;
the driving transistor has the drain connected to the DC high voltage signal, and the source connected to the drain of the control transistor;
the control transistor has the gate connected to a control signal, and the source connected to the positive terminal of the electronic lighting element; and
another terminal of the storage capacitor is connected to the DC high voltage signal.

5. The pixel driving circuit according to claim 4, wherein the electronic lighting element is an organic light emitting diode (OLED).

6. A driving method for a pixel driving circuit, the pixel driving circuit comprising a base pixel circuit, a touch control circuit, and a switch, where the base pixel circuit has a first terminal connected to a DC high voltage signal and a second terminal connected to a positive terminal of an electronic lighting element, the electronic lighting element has a negative terminal connected to a DC low voltage signal, the touch control circuit is connected to a junction between the negative terminal of the electronic lighting element and the DC low voltage signal through the switch, the driving method comprising the steps of
determining a current operation state of the base pixel circuit, where the current operation state of the base pixel circuit is either driving the electronic lighting element to illuminate or preventing the electronic lighting element from illuminating; and
controlling whether the touch control circuit to function or not by closing or opening the switch in accordance with the current operation state of the base pixel circuit.

7. The driving method according to claim 6, wherein the step of controlling whether the touch control circuit to function or not comprises the step of
if the base pixel circuit drives the electronic lighting element to illuminate, the switch is opened and the touch control circuit is prevented from functioning as the touch control circuit is disconnected from the DC low voltage signal.

8. The driving method according to claim 6, wherein the step of controlling whether the touch control circuit to function or not comprises the step of
if the base pixel circuit prevents the electronic lighting element from illuminating, the switch is closed and the touch control circuit functions as the touch control circuit is connected to the DC low voltage signal.

9. The driving method according to claim 6, wherein the touch control circuit comprises an inductive capacitor, a coupling capacitor, an operational capacitor, and an operational amplifier;
the inductive capacitor has a terminal connected to a touch sensitive line, and another terminal connected to a terminal of the switch, a terminal of the coupling capacitor, a terminal of the operational capacitor, and a first input terminal of the operational amplifier;
another terminal of the coupling capacitor is connected to ground;
the operational capacitor has another terminal connected to an output terminal of the operational amplifier, thereby forming a negative feedback amplification circuit with the operational amplifier; and
a second input terminal of the operational amplifier is connected to an internal working voltage signal.

10. The driving method according to claim 6, wherein the base pixel circuit comprises a switch transistor, a driving transistor, a control transistor, and a storage capacitor;
the switch transistor has the gate connected to a scan signal, the drain connected to a data signal, and the source connected to a terminal of the storage capacitor and the gate of the driving transistor;
the driving transistor has the drain connected to the DC high voltage signal, and the source connected to the drain of the control transistor;
the control transistor has the gate connected to a control signal, and the source connected to the positive terminal of the electronic lighting element; and
another terminal of the storage capacitor is connected to the DC high voltage signal.

11. The driving method according to claim 6, wherein the electronic lighting element is an organic light emitting diode (OLED).

12. A display panel comprising a pixel driving circuit, wherein the pixel driving circuit comprises a base pixel circuit, a touch control circuit, and a switch;
the base pixel circuit has a first terminal connected to a DC high voltage signal, and a second terminal connected to a positive terminal of an electronic lighting element; the electronic lighting element has a negative terminal connected to a DC low voltage signal; the base pixel circuit drives or turns off the illumination of the electronic lighting element;
the touch control circuit is connected to a junction between the negative terminal of the electronic lighting element and the DC low voltage signal through the switch; and, based on whether the base pixel circuit drives the electronic lighting element to illuminate, the touch control circuit turn on or off the switch accordingly.

13. The display panel according to claim 12, wherein, if the base pixel circuit drives the electronic lighting element to illuminate, the switch is opened and the touch control circuit is prevented from functioning as the touch control circuit is disconnected from the DC low voltage signal; and
if the base pixel circuit prevents the electronic lighting element from illuminating, the switch is closed and the touch control circuit functions as the touch control circuit is connected to the DC low voltage signal.

14. The display panel according to claim 13, wherein the touch control circuit comprises an inductive capacitor, a coupling capacitor, an operational capacitor, and an operational amplifier;
the inductive capacitor has a terminal connected to a touch sensitive line, and another terminal connected to a terminal of the switch, a terminal of the coupling capacitor, a terminal of the operational capacitor, and a first input terminal of the operational amplifier;
another terminal of the coupling capacitor is connected to ground;
the operational capacitor has another terminal connected to an output terminal of the operational amplifier, thereby forming a negative feedback amplification circuit with the operational amplifier; and
a second input terminal of the operational amplifier is connected to an internal working voltage signal.

15. The display panel according to claim 14, wherein the base pixel circuit comprises a switch transistor, a driving transistor, a control transistor, and a storage capacitor;
the switch transistor has the gate connected to a scan signal, the drain connected to a data signal, and the source connected to a terminal of the storage capacitor and the gate of the driving transistor;
the driving transistor has the drain connected to the DC high voltage signal, and the source connected to the drain of the control transistor;
the control transistor has the gate connected to a control signal, and the source connected to the positive terminal of the electronic lighting element; and
another terminal of the storage capacitor is connected to the DC high voltage signal.

16. The display panel according to claim 15, wherein the electronic lighting element is an organic light emitting diode (OLED).
